(19) United States
(12) Patent Application Publication
(10) Pub. No.: US 2019/0013215 A1
(43) Pub. Date: Jan. 10, 2019

(54) SUBSTRATE HOLDING HAND AND SUBSTRATE CONVEYING APPARATUS INCLUDING THE SAME

(71) Applicants: KAWASAKI JUKOGYO KABUSHIKI KAISHA, Kobe-shi (JP); KAWASAKI ROBOTICS (USA), INC., Wixom, MI (US)

(72) Inventors: Tetsuya YOSHIDA, Kobe-shi (JP); Hajime NAKAHARA, San Jose, CA (US); Mark TANG, Walnut Creek, CA (US)

(73) Assignees: KAWASAKI JUKOGYO KABUSHIKI KAISHA, Kobe-shi (JP); KAWASAKI ROBOTICS (USA), INC., Wixom, MI (US)

(21) Appl. No.: 15/641,825

(22) Filed: Jul. 5, 2017

(51) Int. Cl. H01L 21/677; H01L 21/687; B25J 15/00; B25J 15/08

(52) U.S. Cl. CPC H01L 21/677; B25J 15/08; B25J 15/0014; H01L 21/68707

(57) ABSTRACT

A substrate holding hand is provided, which holds a disc-shaped substrate and includes a base plate, and guide members, each provided to the base plate, formed in an L-shape, and formed so that an inner wall surface thereof is bent when seen horizontally. The inner wall surface of the guide member is formed so that an angle between a first inner wall part that is the furthest portion of the inner wall surface from a bottom surface of the inner wall surface and the bottom surface is larger than an angle between a second inner wall part that is the nearest portion of the inner wall surface to the bottom surface and the bottom surface.

### TECHNICAL FIELD

The present disclosure relates to a substrate holding hand and a substrate conveying apparatus including the same.

### BACKGROUND ART

Semiconductor wafers (semiconductor substrates: hereinafter, may simply be referred to as “the wafer” or “the substrate”) are manufactured in a clean room through multiple processes. The semiconductor wafer is conveyed between the processes by a conveying apparatus which is disposed inside the clean room. A conveying apparatus having a hand part which supports a circumferential edge of the wafer by its inclined supporting surface has been known as the conveying apparatus disposed inside the clean room (e.g., refer to Patent Document 1).

In the conveying apparatus disclosed in Patent Document 1, the hand part which supports the wafer has supporting surfaces (inclined surfaces) inclined by a given angle in thickness directions of the wafer, and the circumferential edge of the wafer is placed on the supporting surfaces.

Moreover, in the conveying apparatus disclosed in Patent Document 1, there is a high possibility of the wafer being supported with inclination with respect to the hand part if an inclination angle α of the inclined surface is small, while the height of wall parts where the supporting surface is formed becomes high if the inclination angle α is too large. Therefore, the inclination angle α is defined to be within a range of 45 to 60 degrees.

Furthermore, in the conveying apparatus disclosed in Patent Document 1, an inner diameter of the wall part between upper ends is made larger than an inner diameter of the wafer. In this example, in a case where the wafer having a diameter of 150±0.5 mm is held, the inner diameter of the wall part between the upper ends is 153 mm when the inclination angle α is 60 degrees.

### SUMMARY OF THE INVENTION

However, even for the conveying apparatus disclosed in Patent Document 1, a difference of the inner diameter between the wafer and the upper ends of the wall parts of the hand part is a little. Therefore, it is difficult to hold the wafer unless the hand part is positioned accurately.

In order to increase the inner diameter between the upper ends of the wall parts, the height of the wall parts may be increased. However, if one wafer is taken out from a Front Opening Unified Pod (FOUP) where a plurality of wafers are stored so as to be spaced apart from each other at a given interval, the height of the wall parts is impossible to be increased. Thus, the hand part needs to be positioned more accurately, and there is still room for an improvement.

One purpose of the present disclosure is to solve the conventional problems and to provide a substrate holding hand and a substrate conveying apparatus including the same, which are capable of easily holding (or gripping) and conveying a substrate.

In order to solve the problems, according to one aspect of the present disclosure, a substrate holding hand holds a disc-shaped substrate and includes a base plate, and guide members, each provided to the base plate, formed in an L-shape, and formed so that an inner wall surface thereof is bent when seen horizontally. The inner wall surface of the guide member is formed so that an angle between a first inner wall part that is the furthest portion of the inner wall surface from a bottom surface of the inner wall surface and the bottom surface is larger than an angle between a second inner wall part that is the nearest portion of the inner wall surface to the bottom surface and the bottom surface.

In this manner, with the substrate holding hand according to this aspect of the present disclosure, a distance between the first inner wall parts of the inner wall surfaces of the guide members increases so that the substrate can easily be held (gripped) and conveyed. Further, since the angle between the second inner wall part and the bottom surface is smaller compared to the first inner wall part, shaking of the substrate is reduced when it is held (gripped) and conveyed.

In addition, a substrate conveying apparatus according to one aspect of the present disclosure includes the substrate holding hand

In this manner, with the substrate conveying apparatus according to this aspect of the present disclosure, a distance between the first inner wall parts of the inner wall surfaces of the guide members increases so that the substrate can easily be held (gripped) and conveyed. Further, since the angle between the second inner wall part and the bottom surface is smaller compared to the first inner wall part, shaking of the substrate is reduced when it is held (gripped) and conveyed.

### BRIEF DESCRIPTION OF DRAWINGS

FIG. 1 is a perspective view schematically illustrating a structure of a semiconductor processing facility provided with a substrate conveying apparatus according to Embodiment 1.

FIG. 2 is a plan view schematically illustrating a structure of the substrate conveying apparatus according to Embodiment 1 and a FOUP.

FIG. 3 is a side view schematically illustrating the structure of the substrate conveying apparatus according to Embodiment 1.

FIG. 4 is a functional block diagram schematically illustrating a configuration of a control device of the substrate conveying apparatus illustrated in FIG. 2.

FIG. 5 is a plan view schematically illustrating a structure of a substrate holding hand illustrated in FIG. 1.

FIG. 6 is an enlarged side view of the vicinity of a guide member of the substrate holding hand illustrated in FIG. 5.

FIG. 7 is a perspective view illustrating a state where the substrate conveying apparatus according to Embodiment 1 operates.

FIG. 8 is a side view schematically illustrating the structure of the substrate holding hand illustrated in FIG. 1.

FIG. 9 is an enlarged side view of the vicinity of guide members of a substrate holding hand according to Embodiment 2.

### MODES FOR CARRYING OUT THE DISCLOSURE

Hereinafter, embodiments of the present disclosure are described with reference to the accompanying drawings. Note that, throughout the drawings, the same reference characters are given to the same or corresponding components to omit redundant description. In addition, throughout the drawings, components for describing the present disclosure are selectively illustrated, and illustration of other components may be omitted. Furthermore, the present disclosure is not limited to the following embodiments.

### Embodiment 1

A substrate holding hand according to Embodiment 1 is a substrate holding hand which holds a disc-shaped substrate, and includes a base plate, and guide members. The guide members are provided to the base plate, formed in an L-shape so that an inner wall surface is bent, when seen horizontally. The inner wall surface of the guide member is formed so that an angle between a first inner wall part which is the furthest portion from the bottom surface and the bottom surface is larger than an angle between a second inner wall part which is the nearest portion to the bottom surface and the bottom surface.

Moreover, in the substrate holding hand according to Embodiment 1, as for the guide member, the inner wall surface may incline so that an angle between the bottom surface and the inner wall surface is an obtuse angle.

Alternatively, in the substrate holding hand according to Embodiment 1, the guide member may be formed so that the angle between the first inner wall part and the bottom surface is 135 to 155 degrees.

Alternatively, in the substrate holding hand according to Embodiment 1, the guide member may be formed so that the angle between the second inner wall part and the bottom surface is 110 to 130 degrees.

Further, the substrate conveying apparatus according to Embodiment 1 includes any one of the substrate holding hands described above.

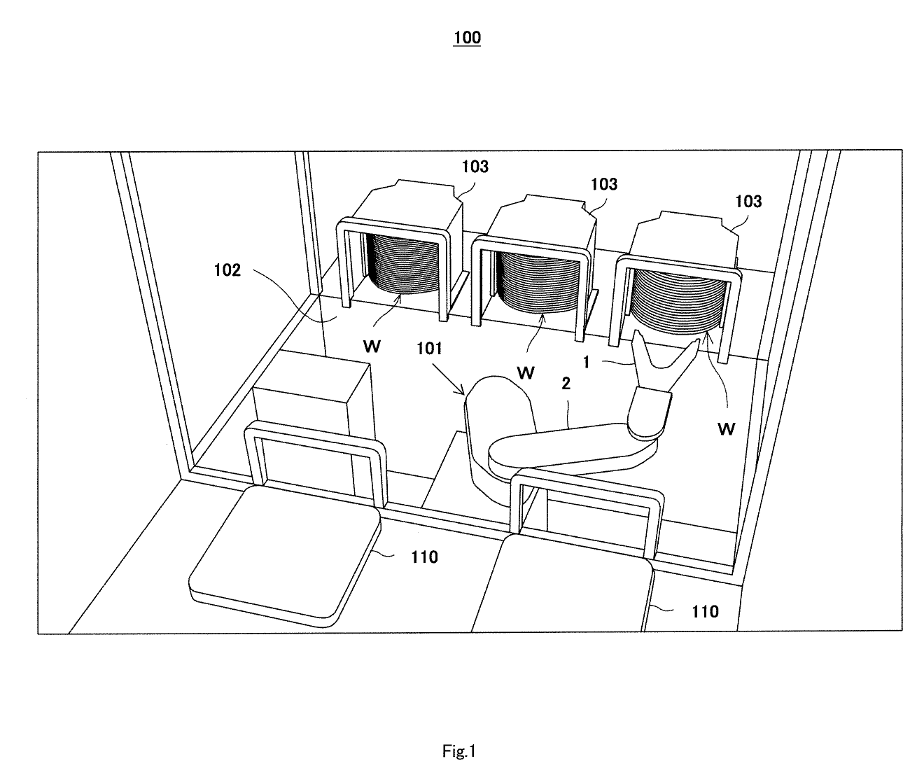

Hereinafter, examples of the substrate holding hand and the substrate conveying apparatus including the same according to Embodiment 1 will be described with reference to FIGS. 1 to 8.

### Structure of Semiconductor Processing Facility

FIG. 1 is a perspective view schematically illustrating a structure of a semiconductor processing facility including the substrate conveying apparatus according to Embodiment 1.

As illustrated in FIG. 1, the semiconductor processing facility 100 is a facility for processing a substrate W, and includes a substrate conveying apparatus 101 according to Embodiment 1, a FOUP 103 which is placed on a base table 102, and a substrate processing apparatus 110. Specifically, the substrate conveying apparatus 101 is configured so that it holds the substrate W stored in the FOUP 103 and conveys the substrate W to the substrate processing apparatus 110, and each processing is performed to the substrate W inside the substrate processing apparatus 110. The processing performed to the substrate W includes, for example, heat treatment, impurities introduction processing, thin film formation processing, lithography processing, cleaning treatment, and flattening treatment.

Next, structures of the substrate conveying apparatus according to Embodiment 1 and the FOUP are described with reference to FIGS. 1 to 4.

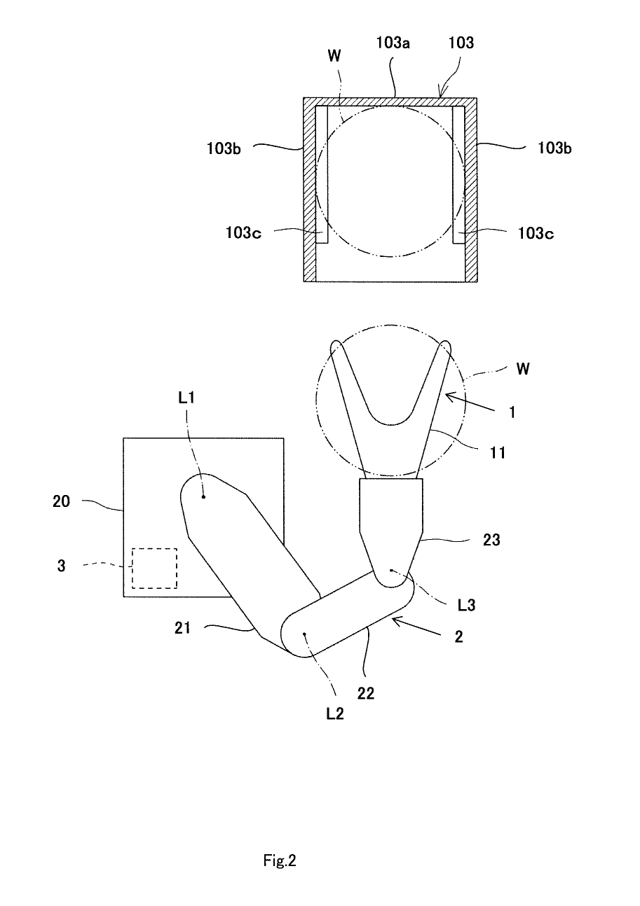

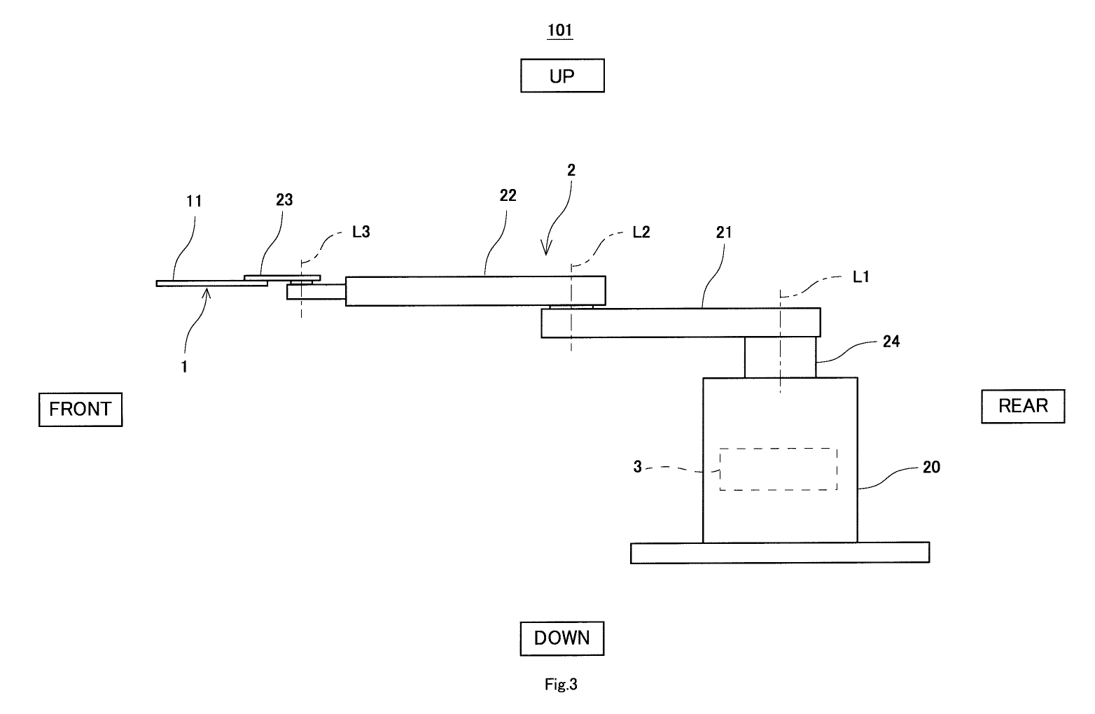

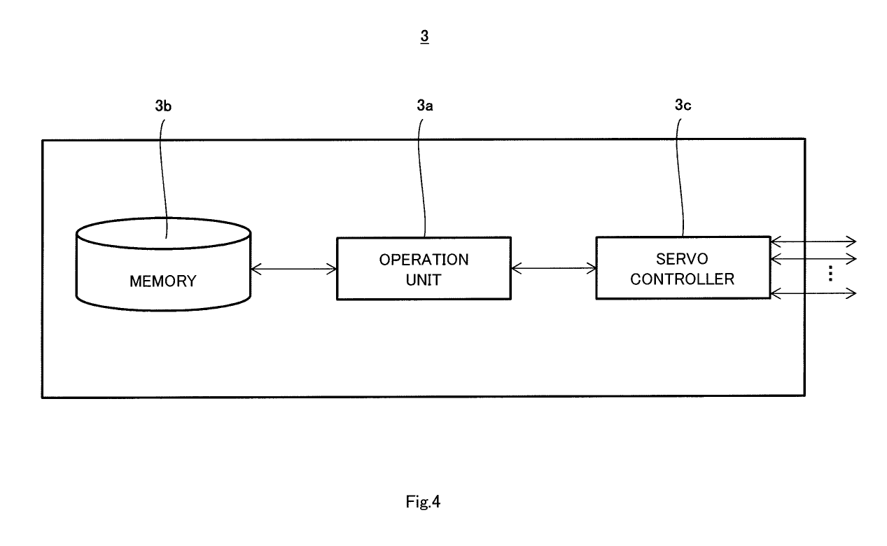

FIG. 2 is a plan view schematically illustrating the structure of the substrate conveying apparatus according to Embodiment 1 and the FOUP. FIG. 3 is a side view schematically illustrating the structure of the substrate conveying apparatus according to Embodiment 1. Moreover, FIG. 4 is a functional block diagram schematically illustrating a configuration of a control device of the substrate conveying apparatus illustrated in FIG. 2.

Note that, in FIG. 2, the FOUP is illustrated as a horizontally-cut cross-section. p Moreover, in FIG. 3, vertical directions and front-and-rear directions of the substrate conveying apparatus are expressed as vertical directions and front-and-rear directions in the drawings.

As illustrated in FIGS. 1 and 2, the FOUP 103 includes a box 103a of which the front is opened, and substrate support parts 103c provided to inner surfaces of a pair of side walls 103b of the box 103a. A plurality of substrates W are stored in the FOUP 103. The substrate support parts 103c are formed in a strip shape, and are provided so as to extend horizontally and to be vertically spaced apart from each other at equal intervals (e.g., 5 to 15-mm interval). The substrate W is placed on upper surfaces of the substrate support parts 103c.

Note that, the substrate W may be a circular thin plate used as material of a substrate of semiconductor devices, such as a semiconductor substrate and a glass substrate, for example. The semiconductor substrate may be a silicon substrate, a sapphire (single crystal alumina) substrate, or various other kinds of substrates, for example. The glass substrate may be a glass substrate for FPD (Flat Panel Display) or a glass substrate for MEMS (Micro Electro Mechanical Systems), for example.

Moreover, as illustrated in FIGS. 1 to 3, the substrate conveying apparatus 101 includes a substrate holding hand 1, a manipulator 2, and a control device 3. Note that, although a structure of a horizontal articulated robot is described below as a structure of the manipulator 2, the manipulator 2 is not limited to the horizontal articulated robot but may be based on a vertical articulated robot.

The manipulator 2 includes a pedestal 20, a first link 21, a second link 22, and a third link 23. The control device 3 is disposed inside the pedestal 20. Moreover, an elevatable shaft 24 is provided to the pedestal 20. The elevatable shaft 24 includes, for example, a ball screw mechanism, a drive motor, a rotary sensor which detects a rotational position of the drive motor, and a current sensor which detects current controlling the rotation of the drive motor (none of them is illustrated). The elevatable shaft 24 is configured to extend and contract vertically. Note that the drive motor may be a servo motor which is servo-controlled by the control device 3, for example. Moreover, the rotary sensor may be an encoder, for example.

A base-end part of the first link 21 is rotatably connected to the elevatable shaft 24 about a rotation axis L1 passing through the axial center of the elevatable shaft 24. A base-end part of the second link 22 is rotatably connected to a tip-end part of the first link 21 about a rotation axis L2. Moreover, a base-end part of the third link 23 is rotatably connected to a tip-end part of the second link 22 about a rotation axis L3. Note that the rotation axis L1, the rotation axis L2, and the rotation axis L3 are parallel to each other, and they are constructed so as to extend vertically in Embodiment 1.

The substrate holding hand 1 is connected to a tip-end part of the third link 23. Note that the substrate holding hand 1 is described later.

Moreover, the manipulator 2 has a drive motor, a power transmission mechanism, a rotary sensor, and a current sensor (none of them is illustrated), for rotating each of the first link 21, the second link 22, and the third link 23 about the respective rotation axes L1-L3 which corresponds to the first link 21, the second link 22, and the third link 23. Note that the drive motor may be a servo motor which is servo-controlled by the control device 3, for example. Moreover, the rotary sensor may be an encoder, for example.

As illustrated in FIG. 4, the control device 3 includes an operation unit 3a, such as a CPU, a memory 3b, such as a ROM and/or a RAM, and a servo controller 3c. The control device 3 is a robot controller provided with a computer, such as a micro controller, for example.

Note that, the control device 3 may be comprised of an independent control device 3 which carries out a centralized control, or may be comprised of a plurality of control devices 3 which collaborate with each other to carry out a distributed control. Moreover, in Embodiment 1, although a mode in which the memory 3b is disposed inside the control device 3 is adopted, it is not limited to this configuration but a mode in which the memory 3b is separately provided from the control device 3 may be adopted.

The memory 3b stores information, such as a basic program of the robot controller, and various fixed data. The operation unit 3a controls various operations of the manipulator 2 by reading and executing software, such as the basic program, stored in the memory 3b. That is, the operation unit 3a generates a control instruction for the manipulator 2, and outputs it to the servo controller 3c. The servo controller 3c is configured so as to control the drive of the servo motor which rotates rotation shafts corresponding to the first link 21 to the third link 23 of the manipulator 2 based on the control instruction generated by the operation unit 3a.

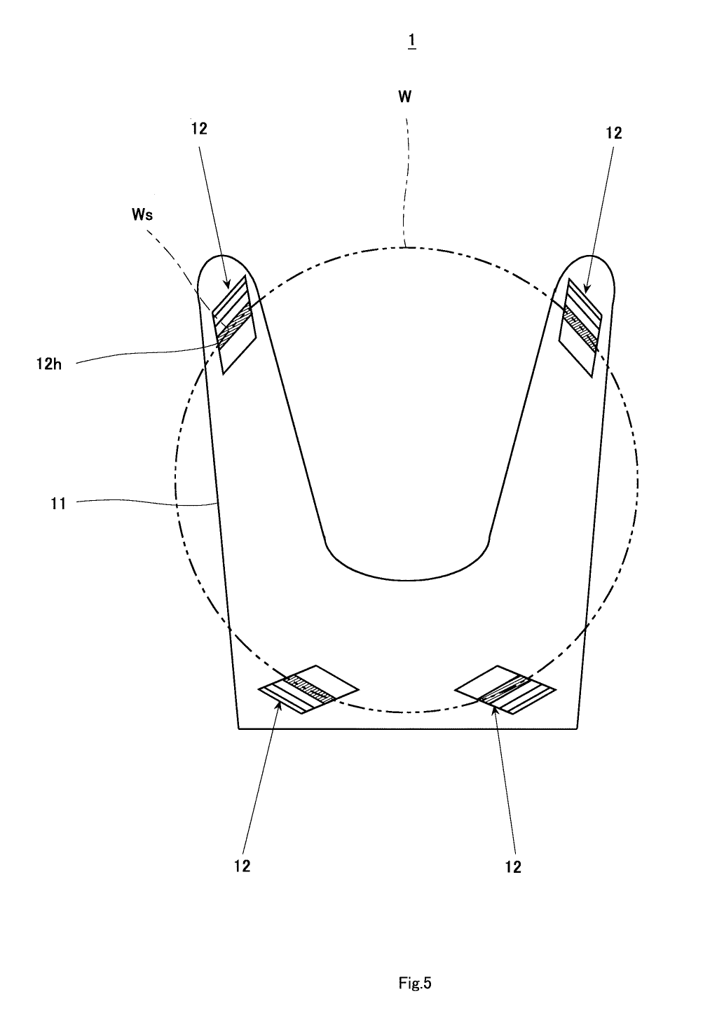

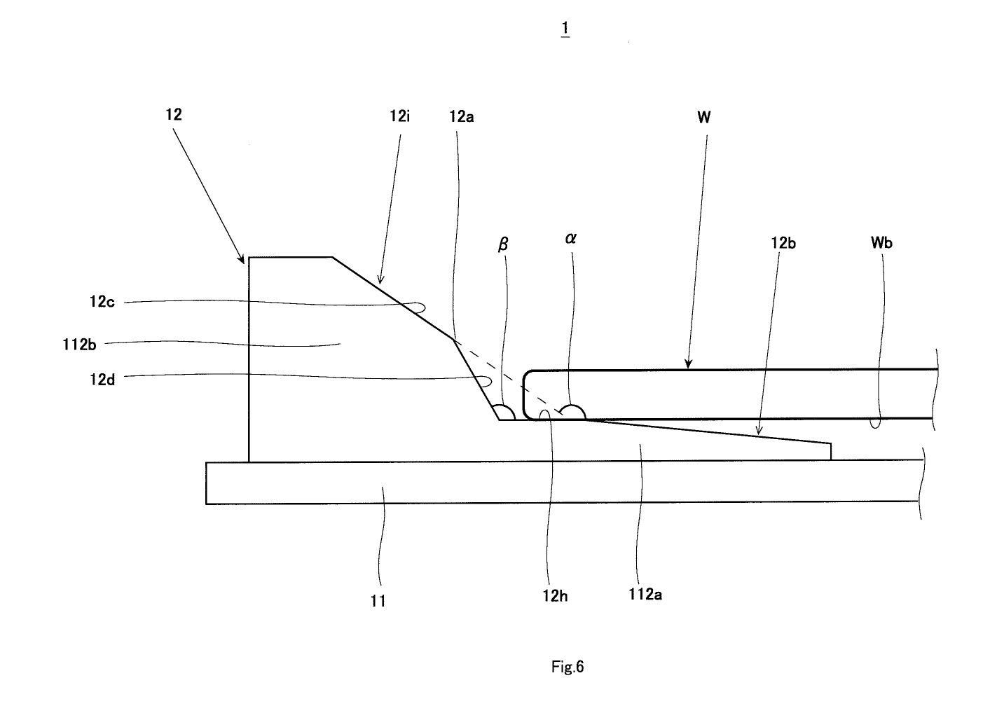

Next, a structure of the substrate holding hand 1 is described in detail with reference to FIGS. 5 and 6.

FIG. 5 is a plan view schematically illustrating the structure of the substrate holding hand illustrated in FIG. 1 (the substrate holding hand according to Embodiment 1). FIG. 6 is an enlarged side view of the vicinity of a guide member of the substrate holding hand illustrated in FIG. 5. Note that, in FIG. 5, horizontal portions of the guide members are hatched.

As illustrated in FIG. 5, the substrate holding hand 1 has a base plate 11 and guide members 12. The base plate 11 is formed in a substantially U-shape (or a substantially Y-shape) in a front view, and constructed so that the substrate W is placed on an upper surface thereof As described above, the substrate W is formed in the disk shape, and it is formed so that a corner part between the substrate W comprised of a main surface (an upper surface or an undersurface) and a circumferential surface is rounded (see FIG. 6). Alternatively, the substrate W may be formed so that the corner part is notched or the corner part is formed. Moreover, a base-end part of the base plate 11 is fixed to the tip-end part of the second link 22 with a suitable fastening member.

The guide members 12 are disposed at at least one location of each of the base-end part and a tip-end part of the base plate 11. That is, at least one guide member 12 is formed in the base-end part of the base plate 11, and at least one guide member 12 is formed in the tip-end part of the base plate 11.

Specifically, the guide members 12 are provided at the suitable locations of the base plate 11 so that end portions of the substrate W is able to be placed on horizontal portions 12h (described later). Note that, in Embodiment 1, two guide members 12 are formed in the base-end part of the base plate 11, and two guide members 12 are formed in the tip-end part of the base plate 11.

Moreover, as illustrated in FIG. 6, the guide member 12 is formed in a substantially L-shape when seen horizontally. Specifically, the guide member 12 extends horizontally, and is comprised of a first portion 112a having a bottom surface 12b, and a second portion 112b extending vertically and having an inner wall surface 12i.

The horizontal portion 12h is formed in a base-end part of the bottom surface 12b of the guide member 12. The horizontal portion 12h is comprised of a plane which is formed parallel to an undersurface Wb of the substrate W. Thus, the substrate W can be held (gripped) horizontally in a state where the substrate conveying apparatus 101 makes the base plate 11 of the substrate holding hand 1 horizontal.

Moreover, a tip-end part of the bottom surface 12b of the guide members 12 is formed in a tapered shape so that its thickness becomes smaller toward the tip end. Thus, a contact area between the bottom surface 12b of the guide member 12 and the undersurface Wb of the substrate W is reduced.

As illustrated in FIG. 5, in Embodiment 1, the horizontal portion 12h is formed in a substantially rectangular shape when seen in the normal direction of the base plate 11 (from above). In detail, the horizontal portion 12h is formed so that a pair of sides thereof are parallel to the tangent of a circumferential surface Ws of the substrate W. Note that the horizontal portion 12h may be formed in a fan shape when seen in the normal direction of the base plate 11 (from above).

Moreover, the guide member 12 may be disposed so that an end portion of the substrate W is placed on part of the horizontal portion 12h, or may be disposed so that the end portion of the substrate W is placed on the entire part of the horizontal portion 12h. In other words, when seen in the normal direction of the base plate 11, the horizontal portion 12h of the guide member 12 may be formed so that some part of the horizontal portion 12h overlaps with the end portion of the substrate W, or may be formed so that the entire part of the horizontal portion 12h overlaps with the end portion of the substrate W.

As illustrated in FIG. 6, the inner wall surface 12i of the guide member 12 is formed so that an angle between the bottom surface 12b and the inner wall surface 12i is an obtuse angle (an angle larger than 90 degrees and smaller than 180 degrees). Moreover, the inner wall surface 12i is formed so that it is bent. Specifically, in Embodiment 1, the inner wall surface 12i is bent at a bent part 12a, and is comprised of a first inner wall part 12c which is the furthest portion from the bottom surface 12b, and a second inner wall part 12d which is the nearest portion to the bottom surface 12b.

The first inner wall part 12c and the second inner wall part 12d are formed so that an angle α between the first inner wall part 12c and the bottom surface 12b (precisely, the horizontal portion 12h) is larger than an angle β between the second inner wall part 12d and the bottom surface 12b (precisely, the horizontal portion 12h).

In addition, the first inner wall part 12c may be formed so that a distance between the upper ends of the inner wall surfaces 12i is increased, and in terms of easily scooping up the substrate W, the angle α between the first inner wall part 12c and the bottom surface 12b is 135 to 155 degrees.

Moreover, in terms of reducing riding and shaking the substrate W on the second inner wall part 12d, the second inner wall part 12d may be formed so that the angle β between the second inner wall part 12d and the bottom surface 12b is 110 to 130 degrees.

### Operation of Semiconductor Processing Facility

Next, operation of the semiconductor processing facility 100 including the substrate conveying apparatus 101 according to Embodiment 1 is described with reference to FIGS. 1 to 7. Note that, since a series of work operations of the manipulator 2 of the substrate conveying apparatus 101, which is comprised of a plurality of processes, is performed similar to those of a well-known manipulator, detailed description thereof is omitted. Moreover, the following operation is performed by the operation unit 3a of the control device 3 reading the program stored in the memory 3b.

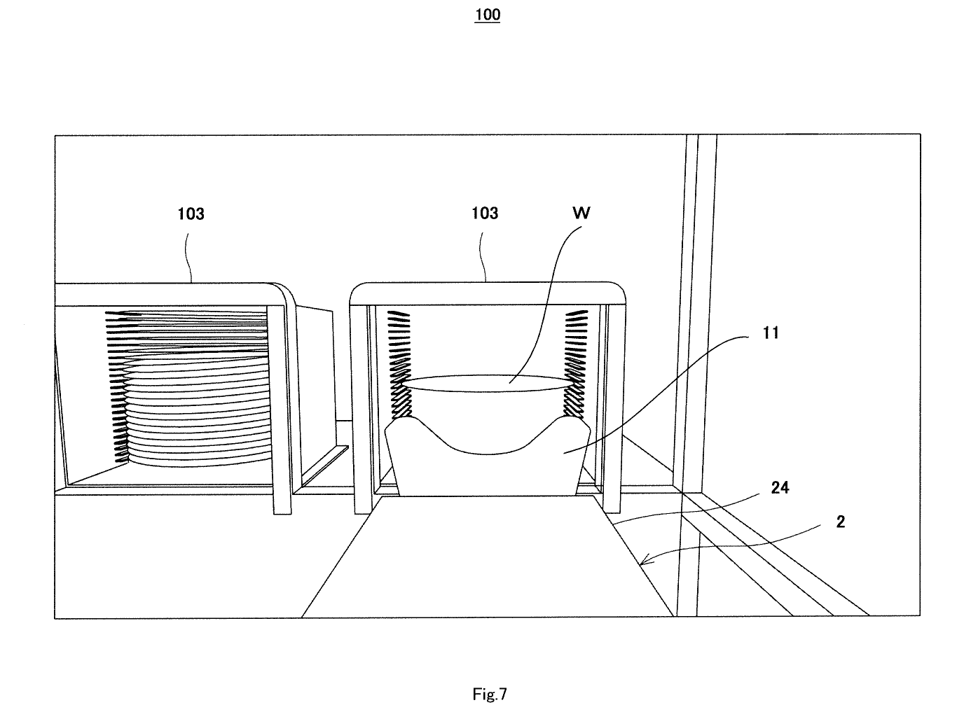

FIG. 7 is a perspective view illustrating a state where the substrate conveying apparatus according to Embodiment 1 operates.

First, when instructing information indicative of executing the series of works to the control device 3 via an input device (not illustrated) is inputted by an operator, the control device 3 operates the manipulator 2 to move it until the substrate holding hand 1 is located in front of the FOUP 103. Here, the control device 3 operates the manipulator 2 so that the substrate holding hand 1 is located under the substrate support parts 103c on which the substrate W to be held is placed (see FIG. 7).

Next, the control device 3 operates the manipulator 2 until the substrate holding hand 1 is located under the substrate W. Here, the control device 3 inserts the substrate holding hand 1 into the FOUP 103 to a position at which the substrate W can be placed on the guide members 12 of the substrate holding hand 1.

Next, the control device 3 operates the manipulator 2 to move the substrate holding hand 1 upwardly, scoop up the substrate W to place the substrate W on the horizontal portions 12h of the guide members 12, and hold the substrate W by the substrate holding hand 1. Subsequently, the control device 3 operates the manipulator 2 so that the substrate holding hand 1 is evacuated from the inside of the FOUP 103 to convey the substrate W to the substrate processing apparatus 110.

Next, the control device 3 operates the manipulator 2 to hold, by the substrate holding hand 1, the substrate W to which given processing is executed inside the substrate processing apparatus 110, and convey it to the substrate processing apparatus 110 etc. which executes the following processing.

### Operations and Effects of Substrate Holding Hand and Substrate Conveying Apparatus Including the Same

Next, operations and effects of the semiconductor processing facility 100 including the substrate conveying apparatus 101 according to Embodiment 1 is described with reference to FIGS. 1 to 8.

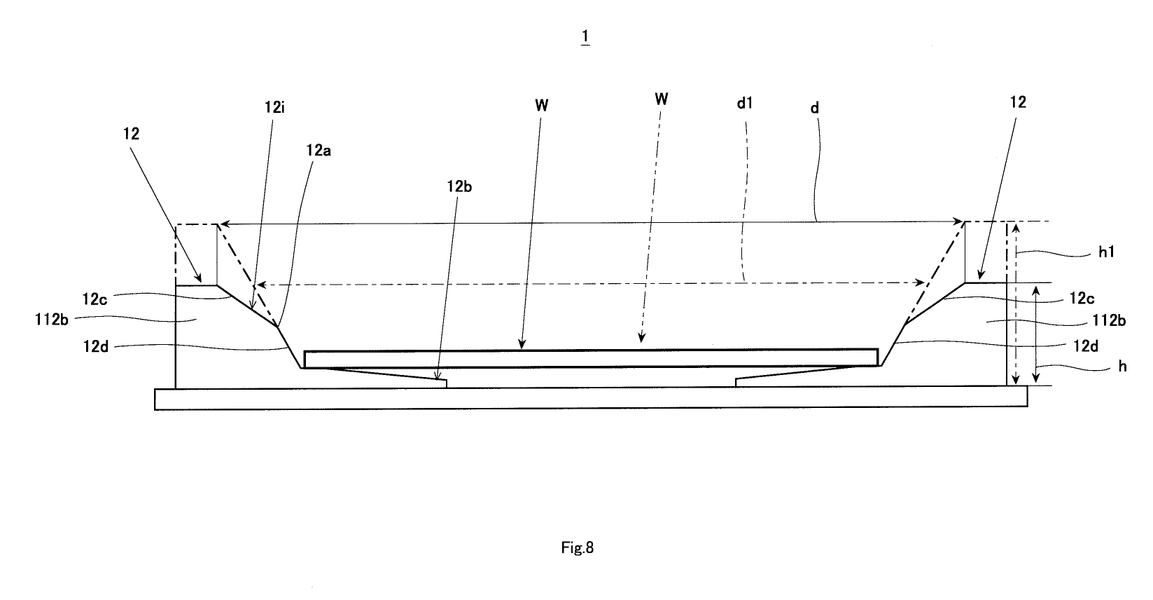

FIG. 8 is a side view schematically illustrating a structure of the substrate holding hand illustrated in FIG. 1.

As illustrated in FIGS. 1 to 8, in the substrate holding hand 1 and the substrate conveying apparatus 101 including the same according to Embodiment 1, the guide member 12 is formed in the L-shape when seen horizontally, and, is formed with the horizontal portions 12h in the base-end parts of the bottom surfaces 12b. Thus, the substrate W can easily be held and conveyed in the horizontal state by placing the substrate W on the horizontal portions 12h of the guide members 12.

In addition, in the substrate holding hand 1 and the substrate conveying apparatus 101 including the same according to Embodiment 1, the guide member 12 is inclined so that the thickness of the tip-end part of the bottom surface 12b of the guide member 12 becomes small toward the tip end. Thus, the bottom surface 12b can firmly fix the guide member 12 to the base plate 11, while reducing the contact area with the undersurface Wb of the substrate W.

Furthermore, in the substrate holding hand 1 and the substrate conveying apparatus 101 including the same according to Embodiment 1, the inner wall surface 12i is bent at the bent part 12a, and the first inner wall part 12c is formed so that the angle α between the first inner wall part 12c and the bottom surface 12b (precisely, the horizontal portion 12h) is larger than the angle β between the second inner wall part 12d and the bottom surface 12b (precisely, the horizontal portion 12h).

Thus, the distance d between two upper ends of the inner wall surfaces 12i of the guide member 12 increases so that the substrate W can easily be scooped up and the control of the manipulator 2 becomes easier.

As illustrated in FIG. 8, in the substrate holding hand 1 and the substrate conveying apparatus 101 including the same according to Embodiment 1, the distance d between the two upper ends of the inner wall surfaces 12i of the two guide members 12 becomes larger than the distance d1 between the upper ends of the inner wall surfaces 12i of the two guide members 12 in the case where the inclination angle of the inclined surface is fixed (see a one-dot chain line of FIG. 8), similar to the conveying apparatus disclosed in Patent Document 1.

Thus, the substrate holding hand 1 and the substrate conveying apparatus 101 including the same according to Embodiment 1 can easily scoop up the substrate W, and the control of the manipulator 2 becomes easier, as compared with the conventional conveying apparatus.

Moreover, as illustrated by the one-dot chain line in FIG. 8, in order to make the distance d1 the same as the distance d when the inclination angle of the inclined surface is fixed, it is necessary to make the height h1 of the wall part greater than the height h of the second portion 112b of the substrate holding hand 1 according to Embodiment 1.

Conversely, in the substrate holding hand 1 and the substrate conveying apparatus 101 including the same according to Embodiment 1, the height h of the second portion 112b of the guide member 12 may be smaller than the height h1 of the wall part of the conveying apparatus disclosed in Patent Document 1.

Thus, in the substrate holding hand 1 and the substrate conveying apparatus 101 including the same according to Embodiment 1, the substrate W can be held and conveyed even when the substrate W is accommodated in a container with a small distance between the substrates W like the FOUP 103.

Moreover, in the substrate holding hand 1 and the substrate conveying apparatus 101 including the same according to Embodiment 1, the angle α between the first inner wall part 12c and the bottom surface 12b may be 135 to 155 degrees.

Thus, the distance d between the upper ends of the inner wall surfaces 12i of the two guide members 12 further increases. Thus, the substrate W can be scooped up more easily, and the control of the manipulator 2 becomes easier.

Furthermore, in the substrate holding hand 1 and the substrate conveying apparatus 101 including the same according to Embodiment 1, the angle β between the second inner wall part 12d and the bottom surface 12b may be 110 to 130 degrees.

Thus, the riding and shaking of the substrate W on the second inner wall part 12d are reduced.

### Embodiment 2

A substrate holding hand according to Embodiment 2 is formed so that inner wall surfaces of guide members are bent by a plurality of steps.

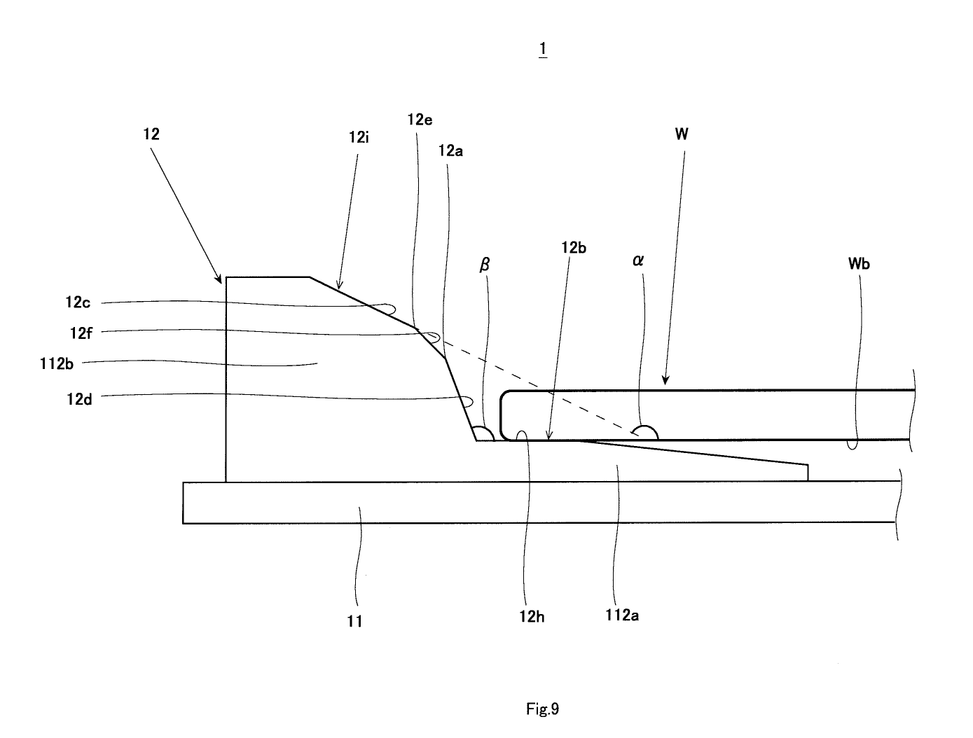

Hereinafter, one example of the substrate holding hand according to Embodiment 2 is described with reference to FIG. 9. Note that since the substrate conveying apparatus including the substrate holding hand according to Embodiment 2 is constructed similar to the substrate conveying apparatus according to Embodiment 1, detailed description thereof is omitted.

### Structure of Substrate Holding Hand

FIG. 9 is an enlarged side view of the vicinity of the guide members of the substrate holding hand according to Embodiment 2.

As illustrated in FIG. 9, the substrate holding hand 1 according to Embodiment 2 is the same in its fundamental structure as the substrate holding hand 1 of Embodiment 1, but it differs in that an inner wall surface 12i of the guide member 12 is formed so as to be bent by a plurality of steps.

Specifically, in Embodiment 2, the inner wall surface 12i is bent at two locations (a bent part 12a and a bent part 12e), and is comprised of a first inner wall part 12c, a second inner wall part 12d, a third wall part 12f which connects the first inner wall part 12c to the second inner wall part 12d. Note that, in Embodiment 2, although a mode where the inner wall surface 12i is bent by two steps (at two locations) is adopted, it is not limited to this structure but the inner wall surface 12i may be bent by a plurality of steps and a mode where the inner wall surface 12i is bent in three or more steps may be adopted.

Even with the substrate holding hand 1 and the substrate conveying apparatus 101 including the same according to Embodiment 2 which are thus constructed, similar operations and effects to the substrate holding hand 1 and the substrate conveying apparatus 101 including the same according to Embodiment 1 are obtained.

It is apparent for a person skilled in the art from the above description that many improvements or other embodiments of the present disclosure are possible. Therefore, the above description is to be interpreted only as illustration and is provided in order to teach a person skilled in the art the best mode that implements the present disclosure. Details of the structures and/or functions of the present disclosure can substantially be changed without departing from the spirit of the present disclosure.

1-6. (canceled)

7. A substrate holding hand configured to hold a substrate, comprising:
a base plate; and
guide members, each provided to the base plate, having a bottom surface on which the substrate is placed, and an inner wall surface located outward of the substrate and protruding from the bottom surface in a thickness direction of the bottom surface, the inner wall surface being bent,
wherein each of the guide members includes a horizontal portion parallel to an undersurface of the substrate so that the substrate is placed on the horizontal portion, and
wherein the inner wall surface of the guide members is comprised of a first inner wall part and a second inner wall part, the first inner wall part is further from the bottom surface than the second inner wall part, and the inner wall surface is formed so that an angle between the first inner wall part and the bottom surface is larger than an angle between the second inner wall part and the bottom surface.

8. The substrate holding hand of claim 7, wherein the inner wall surface of the guide members is formed so as to be bent by a plurality of steps.

9. The substrate holding hand of claim 7, wherein the inner wall surface of the guide members inclines so that an angle between the bottom surface and the inner wall surface is an obtuse angle.

10. The substrate holding hand of claim 7, wherein the guide members are formed so that the angle between the first inner wall part and the bottom surface is 135 to 155 degrees.

11. The substrate holding hand of claim 7, wherein the guide members are formed so that the angle between the second inner wall part and the bottom surface is 110 to 130 degrees.

12. A substrate conveying apparatus comprising the substrate holding hand of claim 7.

13. The substrate holding hand of claim 7, wherein the bottom surface of the guide members has a base-end part on which the substrate is placed, a tip-end part that is formed in a tapered shape so that a thickness of the tip-end part becomes smaller toward a tip end, and the base-end part forms the horizontal portion.

14. The substrate holding hand of claim 7, wherein the inner wall surface of the guide members is formed so that the second inner wall part is steeper than the first inner wall part.

15. The substrate holding hand of claim 7, wherein the inner wall surface of the guide members is formed so that an angle between the first inner wall part and the bottom surface is larger than 90 degrees and smaller than 180 degrees.

16. The substrate holding hand of claim 7, wherein the substrate has a disc shape.

17. The substrate holding hand of claim 7, wherein where the guide members include a first guide member having the first inner wall part and a second guide member having the second inner wall part.

18. The substrate holding hand of claim 7, wherein the substrate holding hand is connected to a manipulator.
